(19) United States
(12) Patent Application Publication
(10) Pub. No.: US 2015/0233551 A1
(43) Pub. Date: Aug. 20, 2015

(54) METHOD OF MANUFACTURING LIGHT SOURCE MODULE AND METHOD OF MANUFACTURING LIGHTING DEVICE

(71) Applicants: Hyoung Cheol CHO, Seoul (KR); Tae Gyu KIM, Hwaseong-si (KR); Tai Oh CHUNG, Suwon-si (KR); Min Soo HAN, Suwon-si (KR)

(72) Inventors: Hyoung Cheol CHO, Seoul (KR); Tae Gyu KIM, Hwaseong-si (KR); Tai Oh CHUNG, Suwon-si (KR); Min Soo HAN, Suwon-si (KR)

(21) Appl. No.: 14/507,544

(22) Filed: Oct. 6, 2014

(30) Foreign Application Priority Data
Feb. 19, 2014 (KR) 10-2014-0019029

(51) Int. Cl. F21V 15/01; H01L 25/075; H01L 33/62; H01L 33/48; F21V 19/00; H05K 13/04

(52) U.S. Cl. CPC F21V 15/01; F21V 19/005; H05K 13/046; H01L 33/62; H01L 33/486; H01L 25/0753; H01L 2933/0033; H01L 2933/0066; H01L 2933/0058

(57) ABSTRACT

There is provided a method of manufacturing a light source module including: preparing a board including circuit wirings and a lens having an accommodation groove formed in a bottom surface thereof; attaching a buffer film to a bottom surface of the accommodation groove of the lens; mounting and arranging a plurality of light emitting devices on one surface of the board such that the plurality of light emitting devices are electrically connected to the circuit wirings; mounting the lens on the board such that the plurality of light emitting devices are accommodated within the accommodation groove in a state in which the buffer film faces the plurality of light emitting devices; and attaching the lens to the board such that the buffer film is tightly attached to upper surfaces of the plurality of light emitting devices and the bottom surface of the accommodation groove.

### CROSS-REFERENCE TO RELATED APPLICATION

This application claims the benefit of Korean Patent Application No. 10-2014-0019029 filed on Feb. 19, 2014, with the Korean Intellectual Property Office, the disclosure of which is incorporated herein by reference.

### BACKGROUND

The present disclosure relates to a method of manufacturing a light source module and a method of manufacturing a lighting device.

In case of manufacturing a light source module using existing flipchip bonding-type light emitting diodes (LEDs), a lens is manufactured such that each LED is encapsulated with resin through a dispensing process. In this case, however, a long period of time is required to cure a resin to form a lens, and in particular, bubbles present in a gap between a flipchip-bonded LED and a board are not removed during a resin curing process, degrading optical performance and reliability. Also, since an amount of dispensed resin is not uniform, lenses respectively covering LEDs do not have the same optical characteristics.

### SUMMARY

An aspect of the present disclosure may provide a method for effectively addressing related art problems in manufacturing a chip-on-board (COB)-type light source module using flipchip bonding-type light emitting diodes (LEDs).

However, aspects of the present disclosure are not limited thereto and aspects and effects that may be recognized from technical solutions or embodiments described hereinafter may also be included although not explicitly mentioned.

According to an aspect of the present disclosure, a method of manufacturing a light source module may include: preparing a board including circuit wirings and a lens having an accommodation groove formed in a bottom surface thereof to be in contact with the board; attaching a buffer film to a bottom surface of the accommodation groove of the lens; mounting and arranging a plurality of light emitting devices on one surface of the board such that the plurality of light emitting devices are electrically connected to the circuit wirings; mounting the lens on the board such that the plurality of light emitting devices are accommodated within the accommodation groove in a state in which the buffer film faces the plurality of light emitting devices; and attaching the lens to the board through thermo-compression such that the buffer film is tightly attached to upper surfaces of the plurality of light emitting devices and the bottom surface of the accommodation groove.

The plurality of light emitting devices may be arranged in a longitudinal direction of the board, and the accommodation groove may extend in the longitudinal direction of the board to integrally cover the plurality of light emitting devices.

The buffer film may extend in the longitudinal direction of the board.

The attaching of a buffer film may include: attaching an exposed upper surface of the buffer film supported by a support film to the bottom surface of the accommodation groove and subsequently removing the support film.

In the mounting of the plurality of light emitting devices, the plurality of light emitting devices may each include electrode pads exposed in the same direction, and the plurality of light emitting devices may be mounted on and electrically connected to the board by connecting the electrode pads and the circuit wirings through flipchip bonding.

The method may further include forming a resin portion filling a space between the plurality of light emitting devices and the board, before mounting the lens and after mounting the plurality of light emitting devices.

The resin portion may be formed by providing a highly thermally conductive filler or a highly light-reflective filler in a resin

The lens may include a flange portion placed on the board so as to be in contact with the board and a lens portion protruded upwardly from the flange portion above the accommodation groove.

The lens portion may extend along the plurality of light emitting devices arranged in the longitudinal direction of the board.

The lens may further include a fixing pin extending from a bottom surface of the flange portion facing the board, and the board may further include a through hole allowing the fixing pin to be inserted thereinto, and in the mounting of the lens on the board, the fixing pin may be inserted into the through hole such that an end portion of the fixing pin is partially protruded through the board from an outer surface of the board.

In the attaching of the lens to the board, the lens may be fixed to the board through thermo-compression such that the end portion of the fixing pin partially protruded to the outer surface of the board is radially spread on the outer surface of the board.

The board may have a recess formed along the circumference of the through hole in order to accommodate the end portion of the fixing pin radially spread on the outer surface thereof.

According to another aspect of the present disclosure, a method of manufacturing a light source module may include: preparing a board on which a plurality of light emitting devices are mounted and arranged in a longitudinal direction on one surface thereof and a lens having an accommodation groove accommodating the plurality of light emitting devices; attaching a buffer film to a bottom surface of the accommodation groove of the lens; mounting the lens on the board such that the buffer film faces the plurality of light emitting devices; and attaching the lens to the board through thermo-compression such that the buffer film is tightly attached to upper surfaces of the plurality of light emitting devices and the bottom surface of the accommodation groove.

The attaching of a buffer film may include: attaching an exposed upper surface of the buffer film supported by a support film to a bottom surface of the accommodation groove and subsequently removing the support film.

The buffer film may extend in the longitudinal direction of the board, together with the accommodation groove.

The lens may include a flange portion disposed to be in contact with the board and extending in the longitudinal direction of the board and a lens portion protruded upwardly from the flange portion and extending in the longitudinal direction of the board above the accommodation groove.

According to another aspect of the present disclosure, a method of manufacturing a light source module may include: preparing a board including circuit wirings and a lens having an accommodation groove formed in a bottom surface thereof to be in contact with the board; attaching a buffer film to a bottom surface of the accommodation groove of the lens; mounting and arranging a plurality of light emitting devices on one surface of the board such that the plurality of light emitting devices are electrically connected to the circuit wirings; mounting the lens on the board such that the plurality of light emitting devices are accommodated within the accommodation groove in a state in which the buffer film faces the plurality of light emitting devices; attaching the lens to the board through thermo-compression such that the buffer film is tightly attached to upper surfaces of the plurality of light emitting devices and the bottom surface of the accommodation groove; and mounting the light source module in a housing.

The attaching of a buffer film may include: attaching an exposed upper surface of the buffer film supported by a support film to a bottom surface of the accommodation groove and subsequently removing the support film.

The method may further include: fastening a cover to the housing to cover the light source module.

The method may further include: fastening a heat sink to the housing.

In another general aspect, the instant application describes a method of manufacturing a light source module comprising: mounting a light emitting device on a board by connecting an electrode pad of the light emitting device to a wiring of the board; and attaching a buffer film to a bottom surface of an accommodation groove of the lens and mounting the lens on the board such that the buffer film faces an upper surface the light emitting device and is tightly attached to the upper surface of the light emitting device and the bottom surface of the accommodation groove, wherein a reflective index of the buffer film is greater than that of the light emitting device and smaller than or equal to that of the lens.

The above general aspect may include one or more of the following features. The attaching of the buffer film may include attaching an exposed upper surface of the buffer film supported by a support film to the bottom surface of the accommodation groove and subsequently removing the support film.

The method may further include mounting the light source module in a housing; and fastening a cover to the housing to cover the light source module. The method may further include mounting the light source module in a housing; and fastening a heat sink to the housing.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a light source module according to an exemplary embodiment of the present disclosure;

FIG. 2 is a cross-sectional view of the light source module of FIG. 1;

FIG. 3 is a cross-sectional view schematically illustrating a light emitting device that may be employed in the light source module of FIG. 1;

FIGS. 4 and 5 are cross-sectional views schematically illustrating light emitting devices according to other exemplary embodiments of the present disclosure;

FIGS. 6A through 6E are cross-sectional views illustrating major processes in a method of manufacturing a nanostructure semiconductor light emitting device according to an exemplary embodiment of the present disclosure;

FIGS. 7A and 7B are plan views illustrating the shapes of openings that may be formed in a mask according to an exemplary embodiment of the present disclosure;

FIGS. 8A and 8B are cross-sectional views illustrating the shapes of openings that may be formed in a mask according to an exemplary embodiment of the present disclosure;

FIGS. 9A through 9E are cross-sectional views illustrating major processes in forming an electrode that may be applied to the nanostructure semiconductor light emitting device obtained in FIG. 6E;

FIGS. 10A and 10B are schematic views illustrating a heat treatment process;

FIGS. 11A through 11D are cross-sectional views illustrating processes for forming nanocores;

FIG. 12 is a CIE 1931 color space chromaticity diagram;

FIGS. 13A and 13B are an enlarged view and a plan view schematically illustrating a modified example in which a light emitting device is mounted in FIG. 2;

FIGS. 14A and 14B are cross-sectional views schematically illustrating modified examples of a light source module, respectively;

FIGS. 15A through 22 are views schematically illustrating sequential processes in a method of manufacturing a light source module according to an exemplary embodiment of the present disclosure;

FIG. 23 is an exploded perspective view schematically illustrating a lighting device according to an exemplary embodiment of the present disclosure;

FIG. 24 is an exploded perspective view schematically illustrating a lighting device according to another exemplary embodiment of the present disclosure; and

FIG. 25 is a bottom view of the lighting device of FIG. 24.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

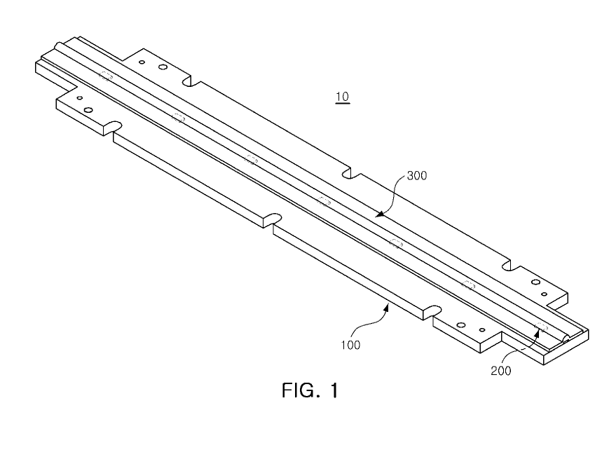

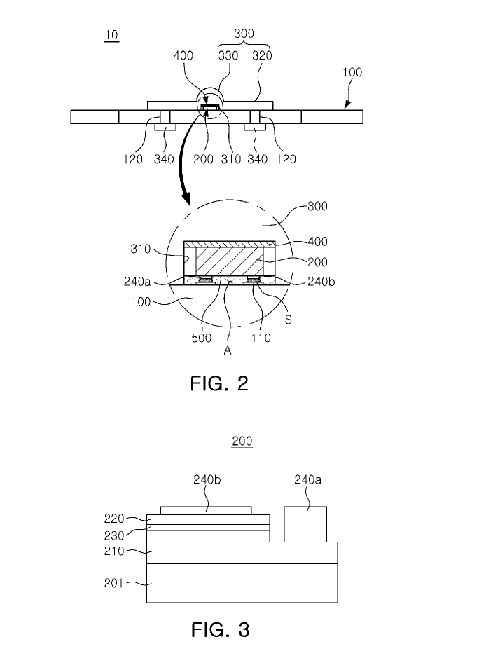

A light source module according to an exemplary embodiment of the present disclosure will be described with reference to FIGS. 1 and 2. FIG. 1 is a perspective view schematically illustrating a light source module according to an exemplary embodiment of the present disclosure, and FIG. 2 is a cross-sectional view of the light source module of FIG. 1.

Referring to FIGS. 1 and 2, a light source module 10 according to an exemplary embodiment may include a board 100, a plurality of light emitting devices 200 mounted on the board 100, a lens 300 attached to the board 100, and a buffer film 400 interposed between the plurality of light emitting devices 200 and the lens 300.

The board 100 may be an FR4-type printed circuit board (PCB) or a flexible printed circuit board (FPCB) and may be formed of an organic resin material containing epoxy, triazine, silicon, polyimide, or the like, or any other organic resin material. The board 100 may also be formed of a ceramic material such as silicon nitride, AlN, Al₂O₃, or the like, or may be formed of a metal or metallic compound such as a metal-core printed circuit board (MCPCB), a metal copper clad laminated (MCCL), or the like.

The board 100 may have a rectangular shape elongated in a longitudinal direction and have a solid or flexible plate structure. For example, the board 100 may have a structure satisfying standards defined in Zhaga standard modules.

A plurality of light emitting devices 200 may be mounted and arranged in a row on one surface of the board 100. The plurality of light emitting devices 200 may be electrically connected to circuit wirings 110 provided on the board 100.

As the light emitting devices 200, any photoelectric element may be used as long as it generates light having a predetermined wavelength through driving power applied from the outside. Typically, the light emitting devices 200 may include a semiconductor light emitting diode (LED) in which semiconductor layers are epitaxially grown on a growth substrate. The light emitting devices 200 may emit blue, green, or red light according to a material or a phosphor contained therein, and may emit white light, ultraviolet light, or the like.

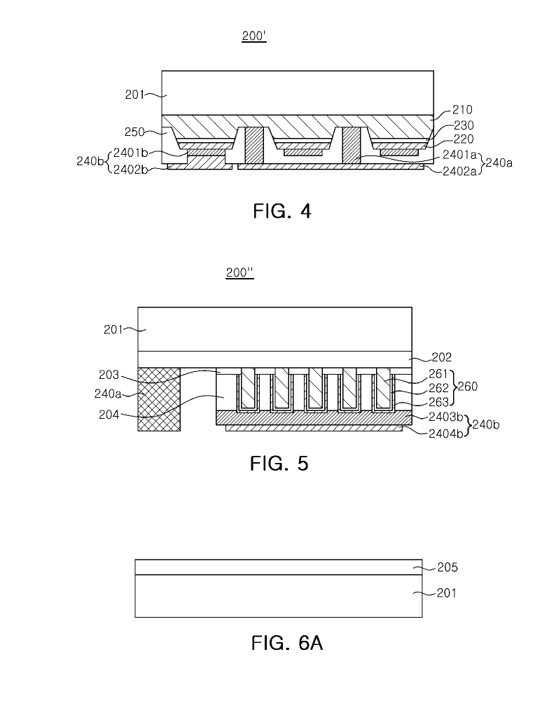

FIGS. 3 through 5 schematically illustrate various examples of light emitting devices employable in a light source module according to an exemplary embodiment of the present disclosure. FIG. 3 is a cross-sectional view schematically illustrating a light emitting device that may be employed in the light source module of FIG. 1, and FIGS. 4 and 5 are cross-sectional views schematically illustrating light emitting devices according to other exemplary embodiments of the present disclosure.

Referring to FIG. 3, the light emitting device 200 may include a first conductivity-type semiconductor layer 210, an active layer 230, and a second conductivity-type semiconductor layer 220 sequentially stacked on a growth substrate 201. In the present disclosure, terms such as ‘upper’, ‘upper portion’, ‘upper surface’, ‘lower’, ‘lower portion’, ‘lower surface’, ‘lateral surface’, and the like, are determined based on the drawings, and in actuality, the terms may be changed according to a direction in which an element or a device is disposed.

The first conductivity-type semiconductor layer 210 stacked on the growth substrate 201 may be an n-type nitride semiconductor layer doped with an n-type impurity. The second conductivity-type semiconductor layer 220 may be a p-type nitride semiconductor layer doped with a p-type impurity. However, according to an exemplary embodiment, positions of the first and second conductivity-type semiconductor layers 210 and 220 may be interchanged. The first and second conductivity-type semiconductor layers 210 and 220 may have an empirical formula AlₓIn_{y}Ga_{(1-x-y)}N (here, 0≦x≦1, 0y≦1, 0x+y<1), and, for example, materials such as GaN, AlGaN, InGaN, AlInGaN may correspond thereto.

The active layer 230 disposed between the first and second conductivity-type semiconductor layers 210 and 220 may emit light having a predetermined level of energy through electron-hole recombination. The active layer 230 may include a material having an energy band gap smaller than those of the first and second conductivity-type semiconductor layers 210 and 220. For example, in a case in which the first and second conductivity-type semiconductor layers 210 and 220 are formed of a GaN-based compound semiconductor, the active layer 230 may include an InGaN-based compound semiconductor having an energy band gap smaller than that of GaN. Also, the active layer 230 may have a multi-quantum well (MQW) structure in which quantum barrier layers and quantum well layers are alternately stacked. For example, the active layer 230 may have a multi-quantum well (MQW) structure in which quantum well layers and quantum barrier layers are alternately stacked, for example, an InGaN/GaN structure. However, the present disclosure is not limited thereto and the active layer 230 may have a single quantum well (SQW) structure.

The light emitting device 200 may include first and second electrode pads 240a and 240b electrically connected to the first and second conductivity-type semiconductor layers 210 and 220, respectively. In order to implement a chip-on-board type structure through flipchip bonding, the first and second electrode pads 240a and 240b may be disposed on and exposed from one surface of the light emitting device 200 in the same direction. Here, the one surface of the light emitting device may be defined as a mounting surface of each of the light emitting device 200 mounted on the board 100.

The light emitting device 200 may be mounted on and electrically connected to the board 100 through solder (S) interposed between the first and second electrode pads 240a and 240b and the circuit wirings 110 according to a flipchip bonding scheme.

A light emitting device 200′ illustrated in FIG. 4 includes a semiconductor stacked body formed on a growth substrate 201. The semiconductor stacked body may include a first conductivity-type semiconductor layer 210, an active layer 230, and a second conductivity-type semiconductor layer 220.

The light emitting device 200′ may include first and second electrode pads 240a and 240b respectively connected to the first and second conductivity-type semiconductor layers 210 and 220. The first electrode pad 240a may include a conductive via 2401a connected to the first conductivity-type semiconductor layer 210 through the second conductivity-type semiconductor layer 220 and the active layer 230 and an electrode extending portion 2402a connected to the conductive via 2401a. The conductive via 2401a may be surrounded by an insulating layer 250 so as to be electrically separated from the active layer 230 and the second conductivity-type semiconductor layer 220. The conductive via 2401a may be disposed in a region formed by etching the semiconductor stacked body. The amount, shape, and pitch of conductive vias 2401a, a contact area with respect to the first conductivity-type semiconductor layer 210, and the like, may be appropriately designed such that contact resistance is reduced. The conductive vias 2401a may be arranged in rows and columns on the semiconductor stacked body, improving a current flow. The second electrode pad 240b may be formed on the second conductivity-type semiconductor layer 220 and include an ohmic contact layer 2401b and an electrode extending portion 2402b.

A light emitting device 200″ illustrated in FIG. 5 may include a growth substrate 201, a first conductivity-type semiconductor base layer 202 formed on the growth substrate 201, and a plurality of light emitting nanostructures 260 formed on the first conductivity-type semiconductor base layer 202. The light emitting device 200″ may further include an insulating layer 203 and a filler portion 204.

Each of the plurality of light emitting nanostructures 260 includes a first conductivity-type semiconductor core 261, and an active layer 262 and a second conductivity-type semiconductor layer 263 sequentially formed as shell layers on the first conductivity-type semiconductor core 261.

In the present exemplary embodiment, it is illustrated that each of the light emitting nanostructures 260 has a core-shell structure, but the present disclosure is not limited thereto and each of the light emitting nanostructures may have a different structure such as a pyramid structure. The first conductivity-type semiconductor base layer 202 may be a layer providing a growth surface for the light emitting nanostructures 260. The insulating layer 203 may provide an open region allowing the light emitting nanostructures 260 to be grown, and may be formed of a dielectric material such as SiO₂ or SiNₓ. The filler portion 204 may structurally stabilize the light emitting nanostructures 260 and allows light to be transmitted or reflected. Alternatively, in a case in which the filler portion 204 includes a light-transmissive material, the filler portion 204 may be formed of a transparent material such as SiO₂, SiNx, an elastic resin, silicon, an epoxy resin, a polymer, or plastic. In a case in which the filler portion 204 includes a reflective material, the filler portion 204 may be formed of metal powder or ceramic powder having high reflectivity mixed with a polymer material such as polypthalamide (PPA), or the like, as needed. The highly reflective ceramic powder may be at least one selected from the group consisting of TiO₂, Al₂O₃, Nb₂O₅, and ZnO. Alternatively, a highly reflective metal such as aluminum (Al) or silver (Ag) may be used.

The first and second electrode pads 240a and 240b may be disposed on lower surfaces of the light emitting nanostructures 260. The first electrode pad 240a may be positioned on an exposed upper surface of the first conductivity-type semiconductor base layer 202, and the second electrode pad 240b may include an ohmic contact layer 2403b and an electrode extending portion 2404b formed below the light emitting nanostructures 260 and the filler portion 204. Alternatively, the ohmic contact layer 2403b and the electrode extending portion 2404b may be integrally formed.

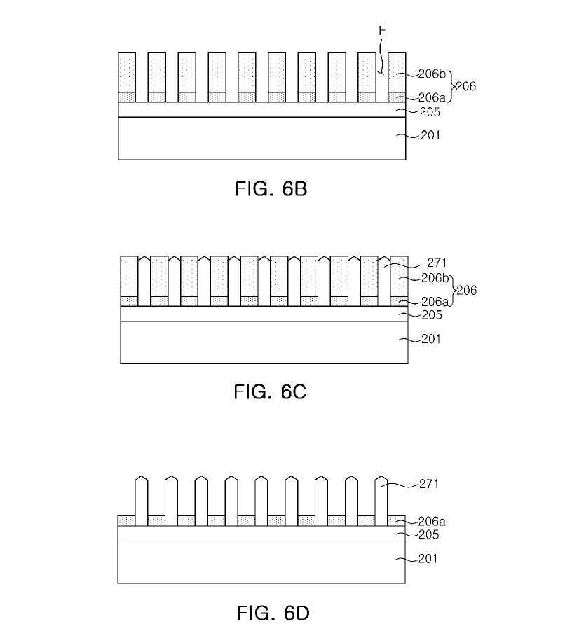

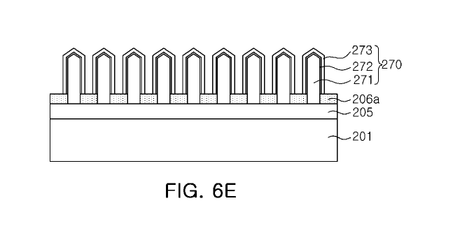

FIGS. 6A through 6E are cross-sectional views illustrating major processes in a method of manufacturing a nanostructure semiconductor light emitting device according to an exemplary embodiment of the present disclosure.

The manufacturing method starts with an operation of providing a base layer 205 formed of a first conductivity-type semiconductor.

As illustrated in FIG. 6A, a first conductivity-type semiconductor may be grown on a growth substrate 201 to provide a base layer 205.

An insulating, conductive, or semiconductive substrate may be used as the growth substrate 201 as needed. The growth substrate 201 may be a crystal growth substrate for growing the base layer 205. In a case in which the base layer 205 is a nitride semiconductor, the growth substrate 201 may be selected from among sapphire, SiC, Si, MgAl₂O₄, MgO, LiAlO₂, LiGaO₂, and GaN.

The base layer 205 may provide a crystal growth surface for allowing light emitting nanostructures 270 to be formed thereon and electrically connect one ends of the plurality of light emitting nanostructures 270. Thus, the base layer 205 is formed as a semiconductor single crystal having electrical conductivity. The base layer 205 may be a crystal satisfying AlₓIn_{y}Ga_{1-x-y}N (0≦x<1, 0≦y<1, 0≦x+y<1).

The base layer 205 may be doped with an n-type impurity such as silicon (Si) to have a particular conductivity type. The base layer may include GaN having an n-type impurity concentration of 1×10¹⁸/cm³ or greater. A thickness of the base layer 205 provided for the growth of nanocores 271 may be 1 μm or greater. A thickness of the base layer 205 may range from 3 μm to 10 μm in consideration of a follow-up electrode forming process, or the like.

In a case in which a nitride semiconductor single crystal is grown as the base layer 205, the growth substrate 201 may be a GaN substrate as a homogenous substrate, and a sapphire, silicon (Si), silicon carbide (SiC) substrate, or the like, may also be used as a heterogeneous substrate. If necessary, a buffer layer (not shown) may be introduced between the growth substrate 201 and the base layer 205 to alleviate a difference in lattice mismatch. The buffer layer (not shown) may be include AlₓIn_{y}Ga_{1-x-y}N (0≦x<1, 0≦y<1, 0≦x+y<1), and in particular, GaN, AlN, AlGaN, InGaN, or InGaAlN. The buffer layer (not shown) may be formed by combining a plurality of layers or by gradually changing a composition.

In a case in which silicon is used as the growth substrate 201, the growth substrate may be bowed or damaged due to a difference in coefficient of thermal expansion between silicon and GaN and there is a high possibility of generating a defect due to a difference in lattice constant. Thus, in order to control stress for restraining bowing, as well as control generation of a defect, a buffer layer having a complex structure may be used. For example, in a case in which a crystal such AlN or SiC without gallium (Ga) is used to prevent a reaction of gallium with silicon (Si) and a plurality of AlN layers are used on the growth substrate 201, an AlGaN intermediate layer may be inserted therebetween in order to control stress.

Before or after growing an LED structure, the growth substrate 201 may be fully or partially removed or patterned during a chip manufacturing process to enhance the optical or electrical characteristics of an LED chip. For example, in the case of a sapphire substrate, the growth substrate may be separated by irradiating a laser onto an interface between the growth substrate 201 and the base layer 205 through the growth substrate, and a silicon or silicon carbide substrate may be removed through a method such as polishing, etching, or the like.

In a case in which the growth substrate is removed, any other support substrate may be used. Such a support substrate may be attached using a reflective metal, or a reflective structure may be inserted into a middle portion of a bonding layer to enhance the light efficiency of an LED chip.

In the case of patterning the growth substrate, an uneven surface or a sloped surface may be formed on a main surface (one surface or both surfaces) or a lateral surface of the growth substrate before or after the growth of the single crystal to enhance light extraction efficiency and crystallinity. A size of the pattern may be selected from within a range of 5 nm to 500 μm, and any pattern may be employed, as long as it can enhance light extraction efficiency as a regular or an irregular pattern. The pattern may have various shapes such as a columnar shape, a peaked shape, a hemispherical shape, or the like.

Subsequently, as illustrated in FIG. 6B, a mask 206 having a plurality of openings H and including an etch-stop layer is formed on the base layer 205.

The mask 206 employed in the present exemplary embodiment may include a first material layer 206a formed on the base layer 205 and a second material layer 206b formed on the first material layer 206a and having an etching rate greater than that of the first material layer 206a under etching conditions of the first material layer 206a.

The first material layer 206a may be provided as an etch-stop layer with respect to the second material layer 206b. Namely, the first material layer 206a has an etching rate lower than that of the second material layer 206b under etching conditions of the second material layer 206b.

The first material layer 206a may be formed of a material having electrical insulation properties, and the second material layer 206b may also be formed of an insulating material as needed. The first and second material layers 206a and 206b may be formed of different materials to obtain a desired difference in etching rates. For example, the first material layer 206a may be formed of SiN, while the second material layer 206b may be formed of SiO₂.

Alternatively, a difference in etching rates may be implemented using air gap density. The second material layer 206b or both the first and second material layers 206a and 206b may be formed of a porous material, and a difference in etching rates between the first and second material layers 206a and 206b may be secured by adjusting a difference in porosity. In this case, the first and second material layers 206a and 206b may be formed of the same material.

A total thickness of the first and second material layers 206a and 206b may be designed in consideration of height of a desired light emitting nanostructure. The first material layer 206a may have a thickness smaller than that of the second material layer 206b. An etch stop level through the first material layer 206a may be positioned at a depth equal to about one-third of the overall height of the mask, or below, namely, the total thickness, of the first and second material layers 206a and 206b from the surface of the base layer 205. In other words, the first material layer 206a may have a thickness equal to about one-third of the overall thickness of the first and second material layers 206a and 206b, or below.

The overall height of the mask 206, namely, the total thickness of the first and second material layers 206a and 206b, may be about 1 pm or higher, preferably, may range from about 5 μm to 10 μm. The first material layer 206a may have a thickness of about 0.5 μm or less.

After the first and second material layers 206a and 206b are sequentially formed on the base layer 205, a plurality of openings H may be formed to expose regions of the base layer 205 (FIG. 6B). A size of each opening H exposing the surface of the base layer 205 may be designed in consideration of a size of a desired light emitting nanostructure. For example, each opening H may have a width (diameter) equal to or smaller than about 300 nm, further, may range from about 50 nm to 500 nm.

Each opening H may be formed using photolithography of a semiconductor process, and for example, each opening H having a high aspect ratio may be formed using a deep-etching process. The aspect ratio of each opening H may be equal to or greater than 5:1, further, equal to or greater than 10:1.

In general, during a deep-etching process, reactive ions generated from plasma or ion beams generated in high vacuum may be used. Compared to wet etching, the deep-etching process as dry etching allows for precision machining of a micro-structure without geometric constraints. A CF-based gas may be used for oxide film etching of the mask 206. For example, an etchant obtained by combining at least one of O₂ and Ar with a gas such as CF₄, C₂F₆, C₃F₈, C₄F₈, or CHF₃ may be used.

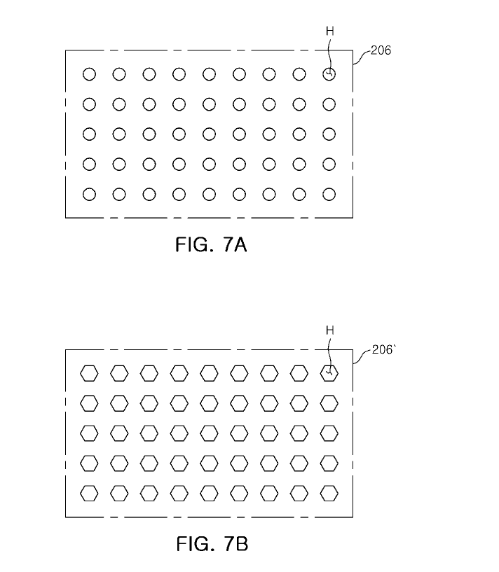

A planar shape and arrangement of the openings H may be variously implemented. For example, in the case of a planar shape, the openings H may be implemented to have various shapes such as polygonal, square, oval, and circular shapes. The mask 206 illustrated in FIG. 6B may have an array of openings H having a circular cross-section as illustrated in FIG. 7A, but the mask 206 may have any other shapes and arrangements as needed. For example, the mask 206 may have an array of openings having a regular hexagonal cross-section, like a mask 206′ as illustrated in FIG. 7B.

The openings H illustrated in FIG. 6B may have a rod structure, but the present disclosure is not limited thereto and the openings H may have various other shapes using an appropriate etching process. Shapes of the openings H may vary according to etching conditions.

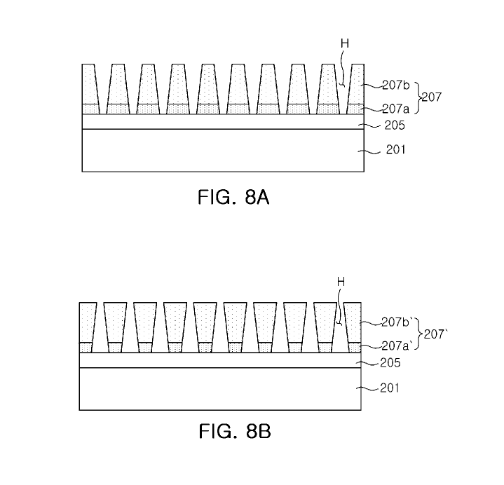

For example, masks having different shapes are illustrated in FIGS. 8A and 8B. Referring to FIG. 8A, a mask 207 including first and second material layers 207a and 207b may have columnar openings H having a width decreased towards a lower portion thereof. On the other hand, referring to FIG. 8B, the mask layer 207′ including first and second material layers 207a ′ and 207b ′ may have columnar openings H having a width increased towards a lower portion thereof.

Thereafter, as illustrated in FIG. 6C, a first conductivity-type semiconductor is grown on the exposed regions of the base layer 205 to fill the plurality of openings H, thus forming a plurality of nanocores 271.

The first conductivity-type semiconductor of the nanocores 271 may be an n-type nitride semiconductor, for example, may be a crystal satisfying n-type AlₓIn_{y}Ga_{1-x-y}N (0≦x<1, 0≦y<1, 0≦x+y<1). The first conductivity-type semiconductor constituting the nanocores may be a material identical to that of the first conductivity-type semiconductor of the base layer 205. For example, the base layer 205 and the nanocores 271 may be formed of n-type GaN.

A nitride single crystal constituting the nanocore 271 may be formed using a metal-organic chemical vapor deposition (MOCVD) or molecular beam epitaxy (MBE), and in this case, the mask 206 acts as a mold of the grown nitride single crystal to provide nanocores 271 corresponding to the shape of the openings H. Namely, the nitride single crystal may be selectively grown on the regions of the base layer 205 exposed by the openings H, filling (or charging) the openings H, and the charged nitride single crystal may have a shape corresponding to that of the openings H.

Subsequently, as illustrated In FIG. 6D, the mask 206 may be partially removed using the first material layer 206a, an etch-stop layer, such that lateral surfaces of the plurality of nanocores 271 are exposed.

In the present exemplary embodiment, by applying an etching process under conditions, only the second material layer 206b may be removed, leaving in place the first material layer 206a. The residual first material layer 206a is employed as an etch stop layer in this etching process and may serve to prevent the active layer 272 and the second conductivity-type semiconductor layer 273 from being connected to the base layer 205 in a follow-up growth process.

Subsequently, as illustrated in FIG. 6E, the active layer 272 and the second conductivity-type semiconductor layer 273 are sequentially grown on the surfaces of the plurality of nanocores 271.

Through this process, each light emitting nanostructure 270 may have a core-shell structure including the nanocore 271 formed of the first conductivity-type semiconductor, the active layer 272 and the second conductivity-type semiconductor layer 273 covering the nanocore 271 as shell layers.

In a case in which the active layer 272 has a multi-quantum well (MQW) structure in which quantum well layers and quantum barrier layers are alternatively stacked, for example, a nitride semiconductor, a GaN/InGaN structure may be used, or alternatively, a single quantum well (SQW) structure may also be used.

The second conductivity-type semiconductor layer 273 may be a crystal satisfying p-type AlₓIn_{y}Ga_{1-x-y}N (0≦x<1, 0≦y<1, 0≦x+y<1). The second conductivity-type semiconductor layer 273 may include an electron blocking layer (not shown) in a portion thereof adjacent to the active layer 272. The electron blocking layer (not shown) may have a structure in which AlₓIn_{y}Ga_{1-x-y}N (0≦x<1, 0≦y<1, 0≦x+y<1) having different compositions are stacked, or may have one or more layers including Al_{y}Ga_{(1-y)}N (0≦y<1). The electron blocking layer may have a band gap greater than that of the active layer 272, preventing electrons from overflowing to the second conductivity-type semiconductor layer 273 from the active layer 272.

In this manner, the light emitting nanostructures 270 employed in the present exemplary embodiment is illustrated as having a core-shell structure having a rod shape, but the present disclosure is not limited thereto and may have various other shapes such as a pyramidal structure or a structure formed as a combination of pyramidal and rod shapes.

In the present exemplary embodiment, an additional heat treatment process may be introduced during the process of forming the light emitting nanostructures using the mask having openings as a mold in order to enhance crystallinity.

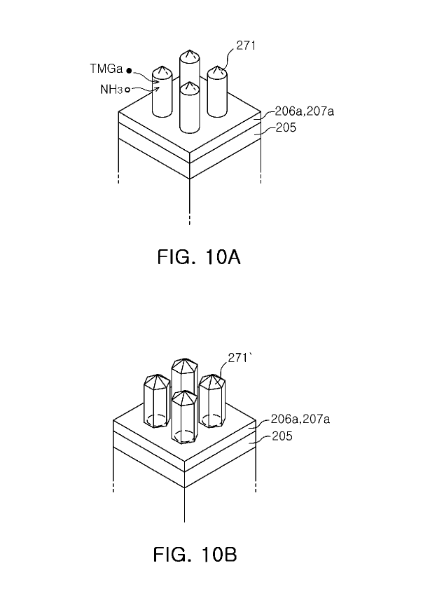

After the mask 206 is removed, the surfaces of the nanocores 271 may be heat-treated under predetermined conditions to change a crystal face of each nanocore 271 into a stable face advantageous for crystal growth, like a semi-polar or non-polar crystal face. This process will be described with reference to FIGS. 10A and 10B.

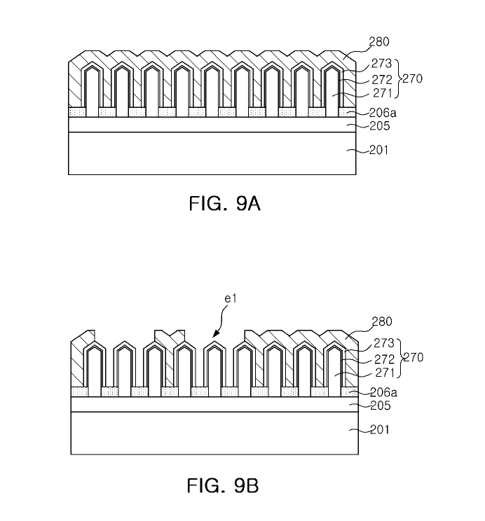

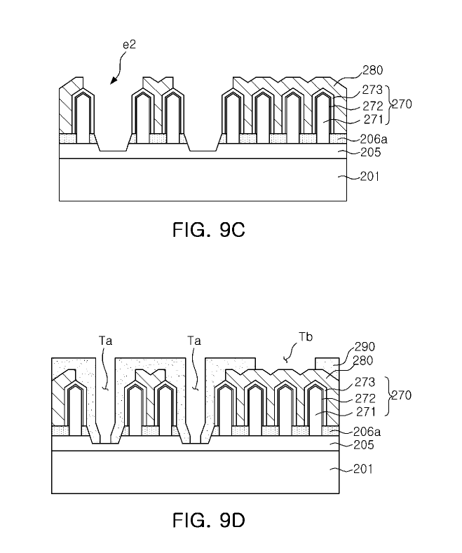

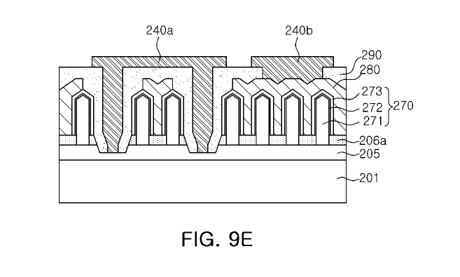

The nanostructure semiconductor light emitting device illustrated in FIG. 6E, may include electrodes formed in various manners. FIGS. 9A through 9E are cross-sectional views illustrating major processes in an example of forming an electrode.

First, as illustrated in FIG. 9A, a contact electrode layer 280 may be formed on the light emitting nanostructures 270 obtained in FIG. 6E.

The contact electrode layer 280 may be obtained by forming a seed layer on surfaces of the light emitting nanostructures 270 and subsequently performing electroplating thereon. The seed layer may be formed of an appropriate material implementing ohmic-contact with the second conductivity-type semiconductor layer 273. The material for ohmic-contact may include at least one of materials such as ZnO, a graphene layer, Ag, Ni, Al, Rh, Pd, Ir, Ru, Mg, Zn, Pt, Au, or the like, and may have a structure including two or more layers such as Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like. For example, after Ag/Ni/Cr layers are formed as seed layers using a sputtering process, Cu/Ni may be plated using electroplating to form the desired contact electrode layer 280.

The contact electrode layer 280 used in the present exemplary embodiment may be a reflective metal layer to extract light in a direction toward the substrate, but the present disclosure is not limited thereto and the contact electrode layer 280 may be formed of a transparent electrode material such as ZnO, graphene, or indium tin oxide (ITO) to extract light in a direction toward the light emitting nanostructures 270.

Although not employed in the present exemplary embodiment, in a case in which a surface of the contact electrode layer 280 is uneven, a planarizing process may be performed to planarize an upper surface of the electrode.

Thereafter, as illustrated in FIG. 9B, electrode regions el positioned in a region in which another electrode is to be formed are selectively removed and expose the light emitting nanostructures 270, and subsequently, as illustrated in FIG. 9C, the exposed light emitting nanostructures 270 are selectively removed to expose partial regions e2 of the base layer 205.

The process illustrated in FIG. 9B is an etching process with respect to an electrode material such as metal, and the process illustrated in FIG. 9C is an etching process with respect to a semiconductor material. Both processes may be performed under different conditions.

Subsequently, as illustrated in FIG. 9D, an insulating layer 290 may be formed such that contact regions Ta and Tb of an electrode are exposed. The contact regions Ta of a first electrode may be provided as exposed regions e2 of the base layer 205, and the contact region Tb of a second electrode may be provided as a partial region of the contact electrode layer 280.

Thereafter, as illustrated in FIG. 9E, first and second electrodes 240a and 240b are formed to be connected to the contact regions Ta and Tb of the first and second electrodes, respectively. As an electrode material used during this process, a common electrode material of the first and second electrodes 240a and 240b may be used. For example, a material for the first and second electrodes 240a and 240b may be Au, Ag, Al, Ti, W, Cu, Sn, Ni, Pt, Cr, NiSn, TiW, AuSn, or a eutectic metal thereof.

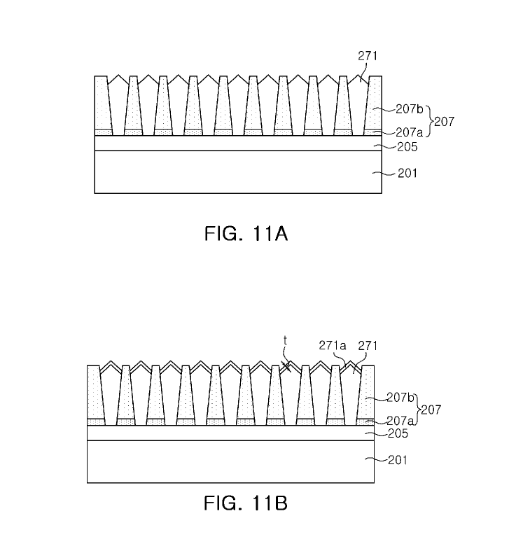

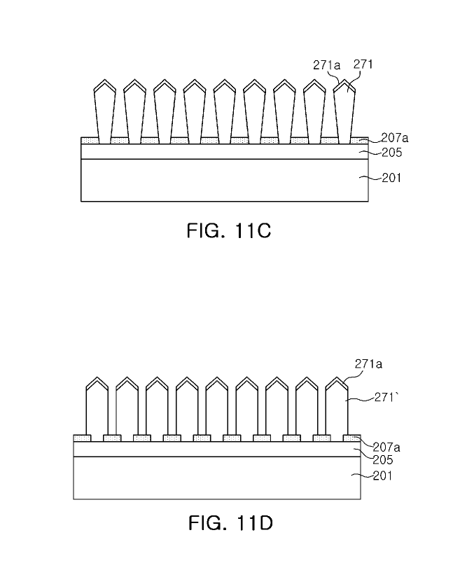

FIGS. 11A through 11D are cross-sectional views illustrating major processes in forming light emitting nanostructures using a mask 207 of a specific example.

As illustrated in FIG. 11A, nanocores 271 may be grown on a base layer 205 using the mask 207. The mask 207 has openings H having a width decreased toward a lower portion thereof. The nanocores 271 may be grown to have a shape corresponding to that of the openings H.

In order to further enhance the crystallinity of the nanocores 271, a heat treatment process may be performed one or more times during the growth of the nanocores 271. In particular, a surface of a tip portion of each nanocore 271 may be rearranged to have hexagonal pyramidal crystal faces, thus obtaining a stable crystal structure and guaranteeing high quality of a crystal grown in a follow-up process.

The heat treatment process may be performed under the temperature condition as described above. For example, for process convenience, the heat treatment process may be performed at a temperature equal or similar to the growth temperature of the nanocores 271. Also, the heat treatment process may be performed in a manner of stopping a metal source such as TMGa, while maintaining pressure and a temperature equal or similar to the growth pressure and temperature of the nanocores 271. The heat treatment process may be continued for a few seconds to tens of minutes (for example, about 5 seconds to 30 minutes), but a sufficient effect may be obtained even with a time duration ranging from approximately 10 seconds to 60 seconds.

The heat treatment process introduced during the growth process of the nanocores 271 may prevent degeneration of crystallinity caused when the nanocores 271 are grown at a fast speed, and thus, fast crystal growth and excellent crystallinity may be promoted.

A time of a heat treatment process section and the number of heat treatment processes for stabilization may be variously modified according to a height and diameter of final nanocores. For example, in a case in which a width of each opening ranges from 300 nm to 400 nm and a height of each opening (thickness of the mask) is approximately 2.0 μm, a stabilization time duration ranging from approximately 10 seconds to 60 seconds may be inserted in a middle point, i.e., approximately 1.0 μm to grow cores having desired high quality. The stabilization process may be omitted according to core growth conditions.

Subsequently, as illustrated in FIG. 11B, a current suppressing intermediate layer 271a, a high resistive layer, may be formed on tip portions of the nanocores 271.

After the nanocores 271 are formed to have a desired height, the current suppressing intermediate layer 271a may be formed on the surfaces of the tip portions of the nanocores 271 with the mask 207 retained as is. Thus, since the mask 207 is used as is, the current suppressing intermediate layer 271a may be easily formed in the desired regions (the surface of the tip portions) of the nanocores 271 without forming an additional mask.

The current suppressing intermediate layer 271a may be a semiconductor layer not doped on purpose or may be a semiconductor layer doped with a second conductivity-type impurity opposite to that of the nanocores 271. For example, in a case in which the nanocores 271 are n-type GaN, the current suppressing intermediate layer 271a may be undoped GaN or GaN doped with magnesium (Mg) as a p-type impurity. In this case, by changing types of an impurity during the same growth process, the nanocores 271 and the current suppressing intermediate layer 271a may be continuously formed. For example, in case of stopping silicon (Si) doping and injecting magnesium (Mg) and growing the same for approximately 1 minute under the same conditions as those of the growth of the n-type GaN nanocores, the current suppressing intermediate layer 271a having a thickness t ranging from approximately 200 nm to 300 nm may be formed, and such a current suppressing intermediate layer 271a may effectively block a leakage current of a few μA or more. In this manner, the current suppressing intermediate layer may be simply formed during the mold-type process as in the present exemplary embodiment.

Subsequently, as illustrated in FIG. 11C, portions of the mask 207 to reach the first material layer 207a as an etch-stop layer are removed to expose lateral surfaces of the plurality of nanocores 271.

In the present exemplary embodiment, by applying the etching process of selectively removing the second material layer 207b, only the second material layer 207b may be removed, while the first material layer 207a may remain. The residual first material layer 207a may serve to prevent the active layer and the second conductivity-type semiconductor layer from being connected to the base layer 205 in a follow-up growth process.

In the present exemplary embodiment, an additional heat treatment process may be introduced during the process of forming the light emitting nanostructures using the mask having openings as a mold in order to enhance crystallinity.

After the second material layer 207b of the mask is removed, the surfaces of the nanocores 271 may be heat-treated under predetermined conditions to change unstable crystal faces of the nanocores 271 into stable crystal faces (please refer to FIGS. 10A and 10B). In particular, in the present exemplary embodiment, the nanocores 271 are grown on the openings having sloped side walls to have the sloped side walls corresponding to the shape of the opening. However, after the heat treatment process is performed, crystals are rearranged and regrown so the nanocores 271′ may have a substantially uniform diameter (or width) greater than that of the openings H (FIG. 11D). Also, the tip portions of the nanocores 271 immediately after being grown may have an incomplete hexagonal pyramidal shape, but the nanocores 271′ after the heat treatment process may have a hexagonal pyramidal shape having uniform surfaces. In this manner, the nanocores having a non-uniform width after the removal of the mask may be regrown (and rearranged) to have a hexagonal pyramidal columnar structure having a uniform width through the heat treatment process.

The lens 300 may be attached to one surface of the board 100 and integrally cover the plurality of light emitting devices 200. The lens 300 may have an accommodation groove 310 on a bottom surface thereof in contact with the board 100.

The lens 300 may include a flange portion 320 placed on the board 100 so as to be in contact with the board and having the accommodation groove 310 provided at the center thereof and a lens portion 330 upwardly protruded from the flange portion 320. The lens portion 330 may have a hemispherically or ovally convex cross-section and extend along with the plurality of light emitting devices 200 arranged in the longitudinal direction of the board 100 together with the accommodation groove 310.

In a case in which the light emitting device 200 has a square shape with a size of 1.32 mm×1.32 mm, for example, the lens portion 330 may have a hemispherical shape having a diameter ranging from 2 mm to 3 mm. In this case, the flange portion 320 constitutes a mechanical portion having a size of 10 mm or greater to secure robustness when mounted on the board 100. Since the lens portion 330 has a hemispherical shape having a diameter ranging from 2 mm to 3 mm, a height of the lens portion 330 may range from 1 mm to 1.5 mm. When the size of the light emitting device 200 is changed and the light emitting device 200 has a square shape, a diameter of the lens portion 330 may have a hemispherical shape having a size not exceeding a distance equal to double a length of one side of the light emitting device.

A fixing pin 340 may extend from a bottom surface of the flange portion 320 facing the board 100. When the lens 300 is attached to the board 100, the fixing pin 340 may be inserted into the board 100 to allow the lens 300 to be firmly fastened to the board 100. A through hole 120 may be provided on the board 100, allowing the fixing pin 340 to be inserted thereinto. In this case, the through hole 120 may serve as a fiducial mark for fastening the lens 300 and the board 100, together with the fixing pin 340. Namely, when attaching the lens 300 to the board 100, a proper position may be recognized by intuition through the through hole 120, and the lens 300 may be easily fastened to the board 100 by inserting the fixing pin 340 into the through hole 120.

The lens 300 may be formed of a resin material having translucency or transparency allowing light emitted by the plurality of light emitting devices 200 to be irradiated outwardly. For example, the material having translucency or transparency may include polycarbonate (PC), polymethylmetacrylate (PMMA), or the like. Also, the lens 300 may be formed of a glass material, but the present disclosure is not limited thereto. The lens 300 may be formed through injection molding using a mold, for example.

In order to adjust an angle of beam spread of light irradiated outwardly through the lens 300, the lens 300 may include a light diffusion material. The light diffusion material may include, for example, SiO₂, TiO₂, Al₂O₃, or the like. An uneven structure may be formed on a surface of the lens 300 and/or on the accommodation groove 310.

The lens 300 may include a wavelength conversion material to convert a wavelength of light irradiated outwardly through the lens 300. For example, at least one or more types of phosphor emitting light having a different wavelength upon being excited by light generated by the plurality of light emitting devices 200 may be contained as a wavelength conversion material. Accordingly, light having various colors including white light may be adjusted to be emitted. In particular, since a phosphor is included in the lens 300, a heat load due to the light emitting devices 200 may be reduced.

For example, when the light emitting device 200 emits blue light, it may be combined with yellow, green, red, and orange phosphors to emit white light. Also, it may include at least one of light emitting devices that emit purple, blue, green, red, and infrared light. In this case, the light emitting device 200 may control a color rendering index (CRI) to range from a sodium-vapor (Na) lamp (40) to a sunlight level (100), or the like, and control a color temperature ranging from 2000K to 20000K to generate various levels of white light. If necessary, the light emitting device 200 may generate visible light having purple, blue, green, red, orange colors, or infrared light to adjust an illumination color according to a surrounding atmosphere or mood. Also, the light emitting device may generate light having a special wavelength stimulating plant growth.

White light generated by combining yellow, green, red phosphors to a blue LED and/or combining at least one of a green LED and a red LED thereto may have two or more peak wavelengths and may be positioned in a segment linking (x, y) coordinates (0.4476, 0.4074), (0.3484, 0.3516), (0.3101, 0.3162), (0.3128, 0.3292), (0.3333, 0.3333) of a CIE 1931 chromaticity diagram illustrated in

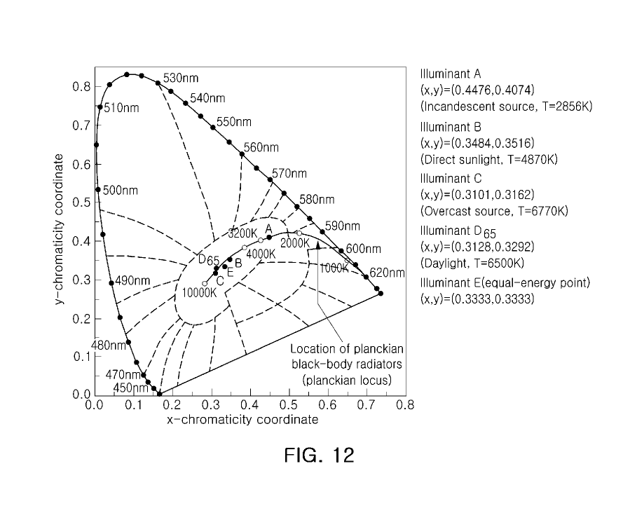

FIG. 12. Alternatively, white light may be positioned in a region surrounded by a spectrum of black body radiation and the segment. A color temperature of white light corresponds to a range from about 2000K to about 20000K.

Phosphors may have the following empirical formula and colors:
Oxides:Yellow and green Y₂A1₅O₁₂:Ce, Tb₂Al₅O₁₂:Ce, Lu₃Al₅O₁₂: Ce
Silicates:Yellow and green (Ba,Sr)₂SiO₄:Eu, Yellow and orange (Ba,Sr)₂SiO₅:Ce
Nitrides:Green β-SiA1ON:Eu, yellow La₃Si₆N₁₁:Ce, orange α-SiAlON:Eu, red CaAlSiN³:Eu, Sr₂Si₅N₈:Eu, SrSiAl₄N₇:Eu Fluorides: KSF-based red K₂SiF₆:Mn4+
Phosphor compositions should basically conform with Stoichiometry, and respective elements may be substituted with different elements of respective groups of the periodic table. For example, strontium (Sr) may be substituted with barium (Ba), calcium (Ca), magnesium (Mg), or the like, of alkali earths, and yttrium (Y) may be substituted with terbium (Tb), Lutetium (Lu), scandium (Sc), gadolinium (Gd), or the like. Also, europium (Eu), an activator, may be substituted with cerium (Ce), terbium (Tb), praseodymium (Pr), erbium (Er), ytterbium (Yb), or the like, according to a desired energy level, and an activator may be applied alone, or a coactivator, or the like, may be additionally applied to change characteristics.

Also, materials such as quantum dots, or the like, may be applied as materials that replace phosphors, and phosphors and quantum dots may be used in combination or alone in an LED.

A quantum dot may have a structure including a core (3 nm to 10 nm) such as CdSe, InP, or the like, a shell (0.5 nm to 2 nm) such as ZnS, ZnSe, or the like, and a ligand for stabilizing the core and the shell, and may implement various colors according to sizes.

Table 1 below shows types of phosphors in applications fields of white light emitting devices using a blue LED (wavelength: 440 nm to 460 nm).

TABLE 1

| Purpose | Phosphor |
|---|---|
| LED TV BLU | β-SiAlON:Eu²⁺ |
| | (Ca,Sr)AlSiN₃:Eu²⁺ |
| | La₃Si₆N₁₁:Ce³⁺ |
| | K₂SiF₆:Mn⁴⁺ |
| Lighting device | Lu₃Al₅O₁₂:Ce³⁺ |
| | Ca-α-SiAlON:Eu²⁺ |
| | La₃Si₆N₁₁:Ce³⁺ |
| | (Ca,Sr)AlSiN₃:Eu²⁺ |
| | Y₃Al₅O₁₂:Ce³⁺ |
| | K₂SiF₆:Mn⁴⁺ |
| Side Viewing | Lu₃Al₅O₁₂:Ce³⁺ |
| (Mobile, | Ca-α-SiAlON:Eu²⁺ |
| Notebook PC) | La₃Si₆N₁₁:Ce³⁺ |
| | (Ca,Sr)AlSiN₃:Eu²⁺ |
| | Y₃Al₅O₁₂:Ce³⁺ |
| | (Sr,Ba,Ca,Mg)₂SiO₄ |
| | K₂SiF₆:Mn⁴⁺ |
| Electrical | Lu₃Al₅O₁₂:Ce³⁺ |
| component | Ca-α-SiAlON:Eu²⁺ |
| (headlamp, etc) | La₃Si₆N₁₁:Ce³⁺ |
| | (Ca,Sr)AlSiN₃:Eu²⁺ |
| | Y₃Al₅O₁₂:Ce³⁺ |
| | K₂SiF₆:Mn⁴⁺ |

The buffer film 400 may be interposed between the plurality of light emitting devices 200 and the lens 300 and may be tightly attached between upper surfaces of the plurality of light emitting devices 200 and an inner surface of the accommodation groove 310. Accordingly, an air gap may be prevented from being generated between the light emitting devices 200 and the lens 300.

In general, semiconductor layers constituting each of the light emitting devices 200 each have a refractive index higher than that of air, and thus, light generated by the light emitting devices 200 may be totally internally reflected from an interface between the upper surfaces of the light emitting devices 200 and air, without moving to outside of the light emitting devices 200. This may leads to a degradation of light extraction efficiency of the light emitting devices 200. This problem may be addressed by bonding the buffer film 400 having a refractive index higher than those of air and the light emitting devices 200 to upper surfaces of the light emitting devices 200. In other words, a refractive index may be adjusted such that light travels toward the lens 300, rather than being totally internally reflected from the interface between the light emitting devices 200 and the buffer film 400. An interface between the buffer film 400 and the lens 300 may also need to satisfy the refractive index condition preventing total internal reflection. In other words, a refractive index of the buffer film 400 may need to be greater than that of each light emitting device 200 and smaller than or at least equal to that of the lens 300. Accordingly, light extraction efficiency of the light emitting device 200 may be increased.

The buffer film 400 may be formed of a material having light transmission characteristics and a certain degree of elasticity. For example, the buffer film 400 may be formed of silicon. The buffer film 400 may extend in a longitudinal direction of the board 100 along the accommodation groove 310.

In order to convert a wavelength of light irradiated to outside through the lens 300, the buffer film 400 may include a wavelength conversion material. For example, at least one or more types of phosphor that emit light having different wavelengths upon being excited by light generated by the light emitting devices 200 may be contained as the wavelength conversion material. Accordingly, the buffer film 400 may be adjusted to emit light of various colors including white light. The buffer film 400 may additionally contain a light diffusion material to evenly mix light from the phosphor(s) and light from the light emitting devices 200. SiO₂, TiO₂, Al₂O₃, or the like, may be used as a light diffusion material.

A resin portion 500 may be further provided on the board 100 in order to fill a space A present between the plurality of light emitting devices 200 and a surface of the board 100. The space A may be formed due to a gap generated between the electrode pads 240a and 240b of the light emitting devices 200 and the circuit wirings 110 of the board 100 according to flipchip bonding.

Although the gap is as fine as tens of micrometers (μm), thermal conductivity is as low as 0.025 W/mK, increasing thermal resistance of the light emitting devices 200.

The resin portion 500 fills the space A through an underfill process, reducing thermal resistance due to air. The resin portion 500 may contain a highly thermally conductive filler in a resin, thus increasing heat dissipation efficiency.

The resin portion 500 may further contain a highly light-reflective filler. Accordingly, an overall amount of light of the light source module 10 may be increased.

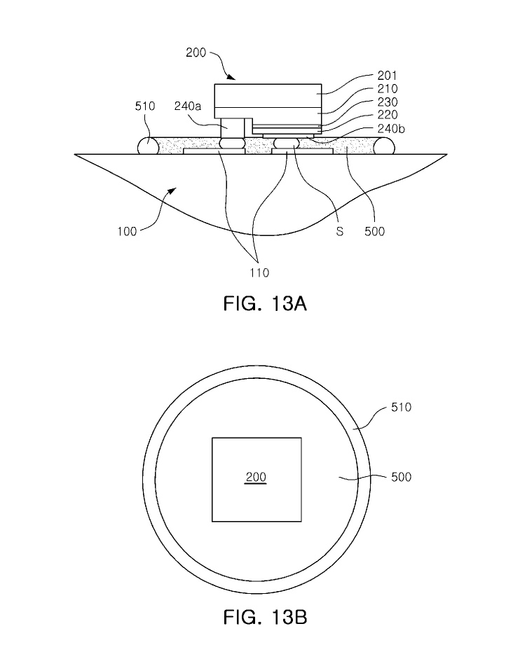

As illustrated in FIGS. 13A and 13B, a protrusion portion 510 defining a region in which the resin portion 500 is formed may further be provided on one surface of the board 100. Accordingly, the resin portion 500 filling the space A may be formed within the region limited by the protrusion portion 510 without flowing out of the board 100. In the present exemplary embodiment, it is illustrated that the protrusion portion 510 has an annular shape surrounding a light emitting device 200, but the present disclosure is not limited thereto.

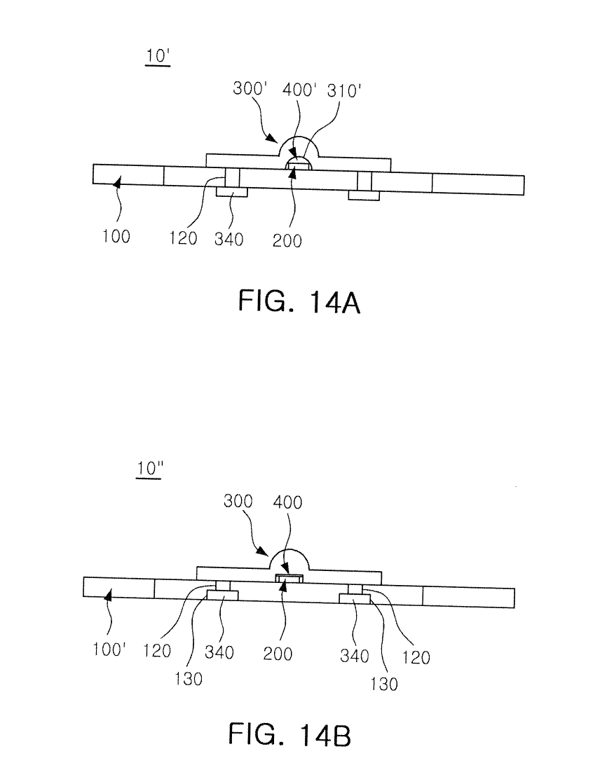

FIGS. 14A and 14B schematically illustrate modified examples of the light source module 10′, 10″ respectively. As illustrated in FIG. 14A, an accommodation groove 310′ of a lens 310′ may have a semicircular curved surface, unlike that of FIG. 1. In this case, a buffer film 400′ may also have a curved surface corresponding to the shape of the accommodation groove 310′.

As illustrated in FIG. 14B, a board 100′ may have a groove 130 accommodating an end portion of a fixing pin 340 of the lens 300 protruded from the other surface of the board 100′ and radially spread. The groove 130 may have a step along the circumference of a through hole 120. Thus, the other surface of the board 100′ may secure flatness facilitating installation of a lighting device, or the like, afterwards.

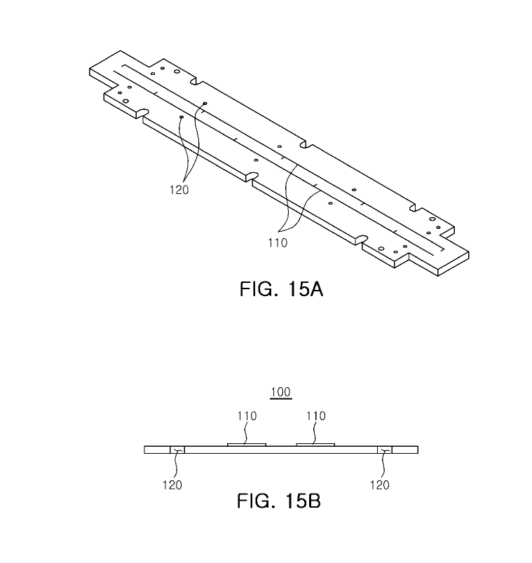

A method of manufacturing a light source module according to an exemplary embodiment of the present disclosure will be described with reference to FIGS. 15 through 22. FIGS. 15 through 22 schematically illustrate sequential processes in a method of manufacturing a light source module according to an exemplary embodiment of the present disclosure.

As illustrated in FIGS. 15A and 15B, a board 100 on which circuit wirings 110 are provided is prepared.

The board 100 may be a general FR4-type PCB and may be formed of an organic resin material containing epoxy, triazine, silicon, polyimide, or the like, or any other organic resin material. Also, the board 100 may be formed of a ceramic material such as silicon nitride, AlN, Al₂O₃, or the like, or may be formed of metal or a metallic compound such as a metal-core printed circuit board (MCPCB), a metal copper clad laminate (MCCL), or the like. The board 100 may be formed as having a rectangular plate-like structure extending in a longitudinal direction.

A plurality of through holes 120 may be provided in the longitudinal direction of the board 100 on the board 100.

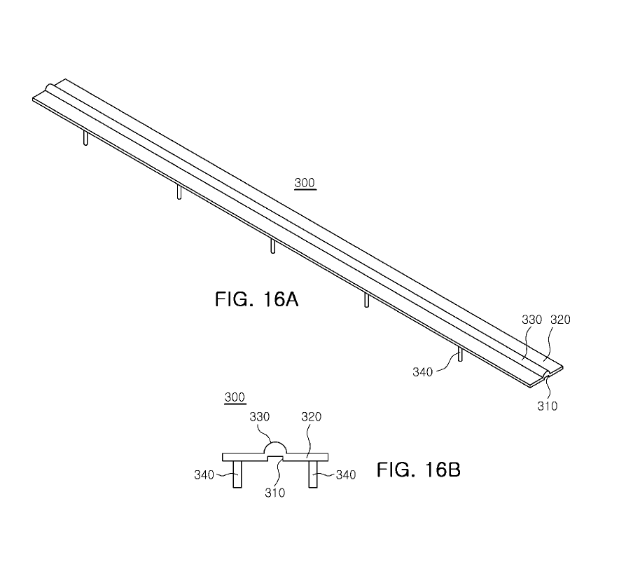

As illustrated in FIGS. 16A and 16B, a lens 300 to be attached to the board 100 may be prepared apart from the board 100. The board 100 and the lens 300 may be separately manufactured and prepared through independent processes.

The lens 300 may have an accommodation groove 310 provided on a bottom surface thereof attached to and in contact with one surface of the board 100. In detail, the lens 300 may include a flange portion 320 placed on the board 100 so as to be in contact with the board and having the accommodation groove 310 provided at the center thereof and a lens portion 330 upwardly protruded from the flange portion 320. The lens portion 330 may have a semi-circularly or ovally convex cross-section and extend in the longitudinal direction of the board 100 together with the accommodation groove 310.

A fixing pin 340 may extend from a bottom surface of the flange portion 320 facing the board 100. The fixing pin 340 may be inserted into the through hole 120 of the board 100 when the lens 300 is attached to the board 100 to allow the lens 300 to be firmly fastened to the board 100.

The lens 300 may be formed of a resin material having translucency or transparency. For example, the material having translucency or transparency may include polycarbonate (PC), polymethylmetacrylate (PMMA), or the like. Also, the lens 300 may be formed of a glass material, but the present disclosure is not limited thereto. The lens 300 may be formed through injection molding using a mold, for example.

The lens 300 may include a light diffusion material. The light diffusion material may include, for example, SiO₂, TiO₂, Al₂O₃, or the like. The lens 300 may also include a wavelength conversion material. A phosphor may be used as the wavelength conversion material and one or more types of phosphors may be contained in the wavelength conversion material.

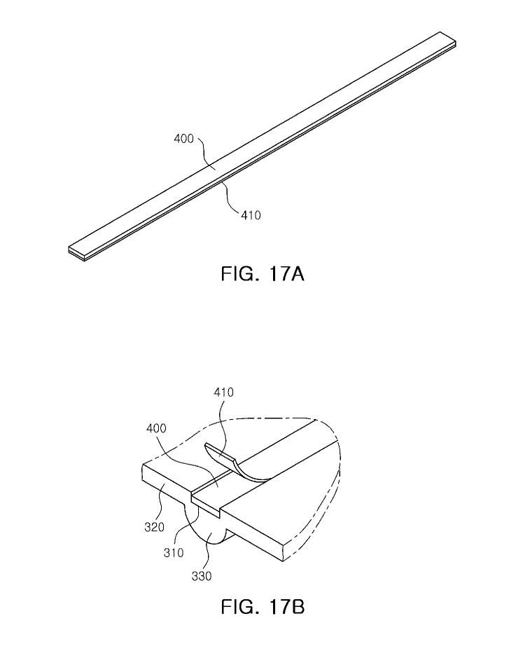

FIGS. 17A and 17B are views schematically illustrating processes in attaching a buffer film 400 to a bottom surface of the accommodation groove 310 of the lens 300.

The buffer film 400 may be formed of a material having light transmission characteristics and a certain degree of elasticity. For example, the buffer film 400 may be formed of silicon. The buffer film 400 may have a band shape extending in the longitudinal direction of the board 100 along the accommodation groove 310 and may be supported by a support film 410.

After an exposed upper surface of the buffer film 400 supported by the support film 410 is attached to a bottom surface of the accommodation groove 310, the support film 410 may be removed to attach the buffer film 400 to the accommodation groove 310.

The support film 410 may be easily removed by peeling the support firm 410 off in the longitudinal direction of the accommodation groove 310 with an end portion of the support film 410 held in the hand of an operator.

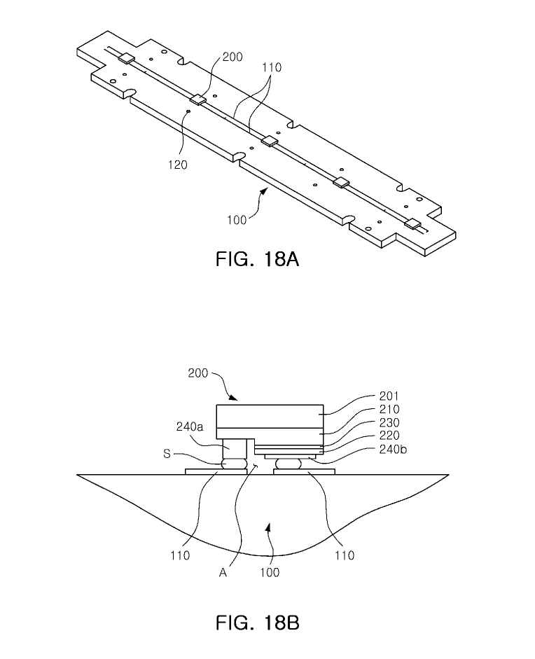

FIGS. 18A and 18B schematically illustrating a process of mounting and arranging a plurality of light emitting devices 200 on one surface of the board 100 such that the plurality of light emitting devices 200 are electrically connected to circuit wirings 110.

A plurality of light emitting devices 200 may be mounted and arranged in a row on one surface of the board 100, and may be electrically connected to the circuit wirings 110 provided on the board 100.

As the light emitting devices 200, any type of photoelectric device may be used as long as the device generates light having a predetermined wavelength by power applied thereto from the outside. Typically, the light emitting device 200 may include a light emitting diode (LED) in which a semiconductor layer is epitaxially grown on a growth substrate. The light emitting devices 200 may emit blue light, green light, or red light according to a material contained therein, and may emit white light.

A first conductivity-type semiconductor layer 210 stacked on the growth substrate 201 may be an n-type nitride semiconductor layer doped with an n-type impurity. A second conductivity-type semiconductor layer 220 may be a p-type nitride semiconductor layer doped with a p-type impurity. The first and second conductivity-type semiconductor layers 210 and 220 may have an empirical formula AlₓIn_{y}Ga_{(1-x-y)}N (here, 0≦x<1, 0≦y<1, 0x+y<1), and, for example, materials such as GaN, AlGaN, InGaN, AlInGaN may correspond thereto.

Each light emitting device 200 may have electrode pads 240a and 240b electrically connected to the first and second conductivity-type semiconductor layers 210 and 220, respectively. In order to implement a chip-on-board type structure through flipchip bonding, the first and second electrode pads 240a and 240b may be disposed on and exposed from one surface of the light emitting device 200 in the same direction. Here, the one surface of each of the light emitting devices may be defined as a mounting surface of each of the light emitting device 200 mounted on the board 100.

The light emitting devices 200 may be mounted on and electrically connected to the board 100 through solder (S) connecting the first and second electrode pads 240a and 240b and the circuit wirings 110 according to a flipchip bonding scheme.

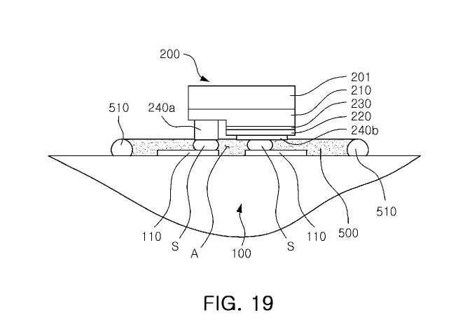

FIG. 19 schematically illustrates an operation of forming a resin portion 500 filling a space A between the plurality of light emitting devices 200 and the board 100.

The resin portion 500 may include a highly thermally conductive filler and/or highly light-reflective filler and fill the space A through an underfill process.

According to an exemplary embodiment, a protrusion portion 510 defining a region in which the resin portion 500 is formed may further be provided on one surface of the board 100. Accordingly, the resin portion 500 filling the space may be formed within the region limited by the protrusion portion 510 without flowing out of the board 100.

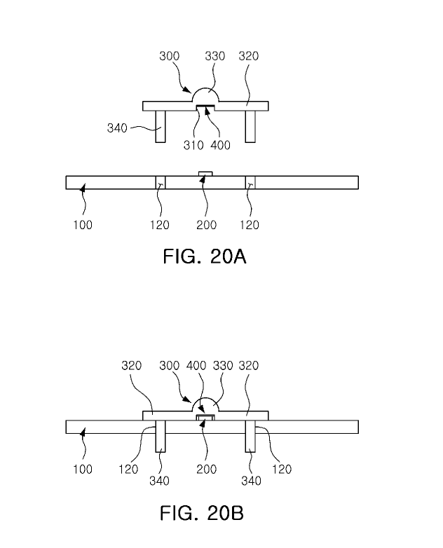

FIGS. 20A and 20B schematically illustrate an operation of mounting the lens 300 on the board 100. The lens 300 may be mounted on the board 100 such that the plurality of light emitting devices 200 are accommodated within the accommodation groove 310 in a state in which the buffer film 400 attached to the interior of the accommodation groove 310 faces the plurality of light emitting devices 200.

In detail, after the lens 300 is disposed such that the fixing pin 340 of the lens 300 is positioned on the through hole 120 of the board 100, the fixing pin 340 is inserted into the through hole 120 such that an end portion of the fixing pin 340 is partially protruded from the other surface of the board 100 through the board 100. With the flange portion 320 of the lens 300 placed on one surface of the board 100, the lens 300 may be mounted on the board 100.

The plurality of light emitting devices 200 may be accommodated within the accommodation groove 310 extending in the longitudinal direction of the board 100 and integrally covered, and in this case, upper surfaces of the plurality of light emitting devices 200 may be in contact with the buffer film 400 attached to a bottom surface of the accommodation groove 310, respectively.

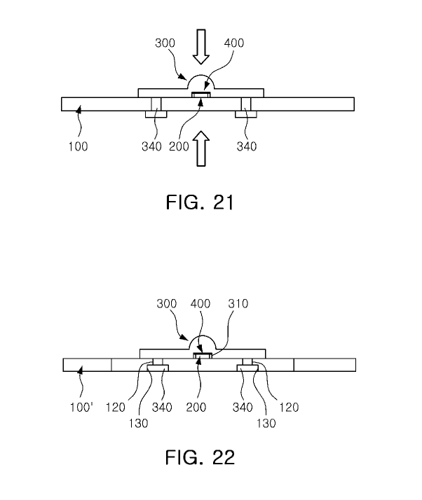

FIG. 21 schematically illustrates an operation of attaching the lens 300 to the board 100 through thermo-compression. With the lens 300 mounted on the board 100, heat and pressure may be applied to the board 100 and the lens 300, respectively, and through the thermo-compression, the lens 300 and the board 100 may firmly be fastened. The thermo-compression process may be performed using an oil-hydraulic press having pressure of 8±1 MPa in a heater having a temperature of 120±10° C. for a process time of 3±1 sec.

Here, an end portion of the fixing pin 340 partially protruded from the outer surface of the board 100 may be deformed to spread radially on theouter surface of the board 100 through thermo-compression, firmly fixing the lens 300 to the board 100 mechanically. In this case, as illustrated in FIG. 22, the board 100 may have a groove 130 formed on the circumstance of the through hole 120 to accommodate the end portion of the fixing pin 340 radially spread on the other surface of the board 100. Thus, the other surface of the board 100 may secure flatness (or become flat) to facilitate installation of a lighting device afterwards.

The buffer film 400 interposed between the lens 300 and the plurality of light emitting devices 200 may be tightly attached to upper surfaces of the plurality of light emitting devices 200 and an inner surface of the accommodation groove 310 through thermo-compression, preventing an air gap from being generated between the light emitting devices 200 and the lens 300.

In manufacturing the chip-on-board type light source module through flipchip bonding, the scheme of attaching the previously processed lens 300 to integrally cover the plurality of light emitting devices 200 is simple and saves time, compared to the related art scheme of forming lenses individually encapsulating a plurality of light emitting devices through a dispensing process. In particular, when a lens is formed through the related art dispensing process, a uniform amount of resin for forming a lens may not be dispensed, making it difficult to manufacture lenses having the equal light characteristics, and air present in a gap between a light emitting device and a board is remains as bubbles, rather than being removed, during a resin curing process, degrading optical performance and reliability of lenses.

In the manufacturing method according to the present exemplary embodiment, the foregoing related art problem may be reduced or eliminated, and the generation of air gap between a lens and a light emitting device according to a lens attaching scheme may be easily addressed by attaching a buffer film. In particular, a buffer film may be easily attached, like a double-sided tape, such that the buffer film supported on a support film is attached to an accommodation groove of a lens and the support tape is removed. Thus, productivity of the light source module may be increased.

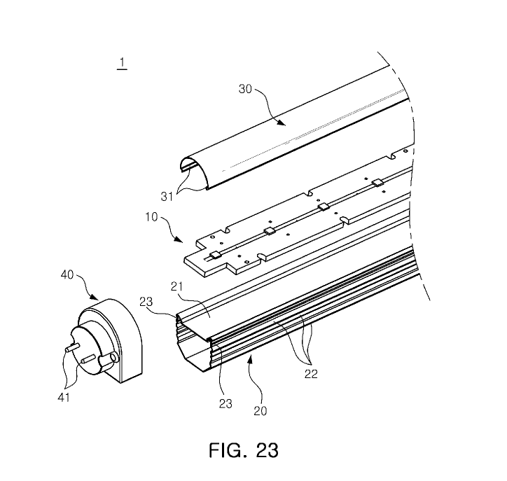

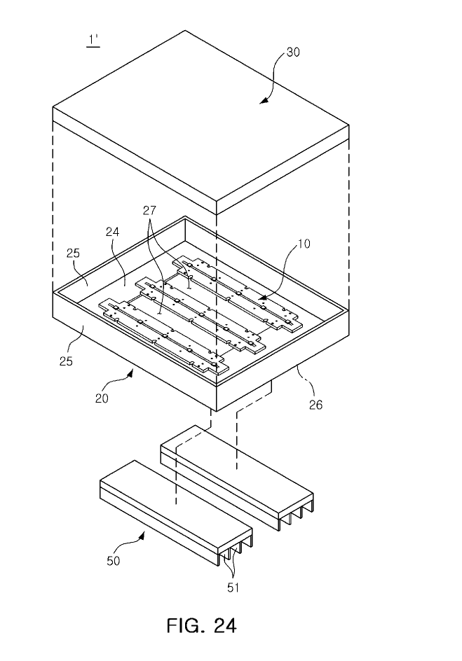

A lighting device according to an exemplary embodiment of the present disclosure will be described with reference to FIG. 23. FIG. 23 is an exploded perspective view schematically illustrating a lighting device according to an exemplary embodiment of the present disclosure.

Referring to FIG. 23, a lighting device 1 may be a bar-type lamp and include a light source module 10, a housing 20, a cover 30, and a terminal 40.

As the light source module 10, the light source module 10 illustrated in FIGS. 1 through 22 may be employed. Thus, detailed descriptions thereof will be omitted. In the present exemplary embodiment, a single light source module 10 is illustrated, but the present disclosure is not limited thereto. For example, a plurality of light source modules may be provided.

The housing 20 may allow the light source module 10 to be fixedly mounted on one surface 21 thereof and dissipate heat generated by the light source module 10 outwardly. To this end, the housing 20 may be formed of a material having excellent thermal conductivity, for example, metal, and a plurality of heat dissipation fins 22 may be protruded from both lateral surfaces of the housing 20 to dissipate heat.

The cover 30 may be fastened to stoppage grooves 23 of the housing 20 to cover the light source module 10. The cover 30 may have a semicircular curved surface to allow light generated by the light source module to be uniformly irradiated to the outside overall. Protrusions 31 may be formed in a longitudinal direction on a bottom surface of the cover 30 and engaged with the stoppage grooves 23 of the housing 20.

The terminal 40 may be provided on at least one open side, among both end portions of the housing 20 in a longitudinal direction to supply power to the light source module 10 and include electrode pins 41 protruded outwardly.

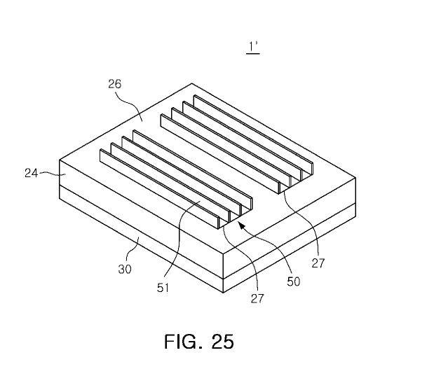

A lighting device 1′ according to another exemplary embodiment of the present disclosure will be described with reference to FIGS. 24 and 25. FIG. 24 is an exploded perspective view schematically illustrating a lighting device according to another exemplary embodiment of the present disclosure, and FIG. 25 is a bottom view of the lighting device of FIG. 24.

Referring to FIGS. 24 and 25, the lighting device 1′ may have, for example, a surface light source-type structure and may include a light source module 10, a housing 20, a cover 30, and a heat sink 50.

As the light source module 10, the light source 10 illustrated in FIGS. 1 through 22 may be employed. Thus, a detailed description thereof will be omitted.

The housing 20 may have a box-shaped structure including one surface 24 and lateral surfaces 25 extending from the circumference of the one surface 24. The housing 20 may be formed of a material having excellent thermal conductivity, for example, a metal, that may dissipation heat generated by the light source module 10 outwardly.

A hole 27 to which the heat sink 50 (to be described below) are insertedly fastened may be formed in the one surface 24 of the housing 10 in a penetrating manner. The light source module 10 mounted on the one surface 24 may partially span the hole 27 so as to be exposed to the outside.

The cover 30 is fastened to the lateral surfaces 25 of the housing 20. The cover 30 may have an overall flat structure.

The heat sink 50 may be fastened to the hole 27 through the other surface 26 of the housing 20. The heat sink 50 may be in contact with the light source module 10 through the hole 27 to dissipate heat from the light source module 10 outwardly. In order to increase heat dissipation efficiency, the heat sink 50 may have a plurality of heat dissipation fins 51. The heat sink 50 may be formed of a material having excellent thermal conductivity, like the housing 20.

As described above, the lighting device using a light emitting device may be applied to an indoor lighting device or an outdoor lighting device according to the purpose thereof. The indoor LED lighting device may include a lamp, a fluorescent lamp (LED-tube), or a flat panel type lighting device replacing an existing lighting fixture (retrofit), and the outdoor LED lighting device may include a streetlight, a security light, a floodlight, a scene lamp, a traffic light, and the like.

Also, the lighting device using LEDs may be utilized as an internal or external light source of a vehicle. As an internal light source, the LED lighting device may be used as an indoor light, a reading light, or as various dashboard light sources of a vehicle. As an external light source, the LED lighting device may be used as a headlight, a brake light, a turn signal lamp, a fog light, a running light, and the like.

In addition, the LED lighting device may also be applicable as a light source used in robots or various mechanic facilities. LED lighting using light within a particular wavelength band may promote plant growth and stabilize a person's mood or treat diseases using emotional lighting.

The lighting device using a light emitting may be altered in terms of an optical design thereof according to a product type, a location, and a purpose. For example, in relation to the foregoing emotional illumination, a technique for controlling lighting by using a wireless (remote) control technique utilizing a portable device such as a smartphone may be provided, in addition to a technique of controlling color, temperature, brightness, and hue of illumination

In addition, a visible wireless communications technology aimed at simultaneously achieving a unique purpose of an LED light source and a purpose of a communications unit by adding a communications function to LED lighting devices and display devices may be available. This is because an LED light source has a longer lifespan and excellent power efficiency, implements various colors, supports a high switching rate for digital communications, and is available for digital control, in comparison with existing light sources.

The visible light wireless communications technology is a wireless communications technology transferring information wirelessly by using light having a visible light wavelength band recognizable by the naked eye. The visible light wireless communications technology is distinguished from a wired optical communications technology in that it uses light having a visible light wavelength band and that a communications environment is based on a wireless scheme.

Also, unlike RF wireless communications, the visible light wireless communications technology has excellent convenience and physical security properties as it can be freely used without being regulated or needing permission in the aspect of frequency usage, is differentiated in that a user can physically check a communications link, and above all, the visible light wireless communications technology has features as a convergence technology that obtains both a unique purpose as a light source and a communications function.

As set forth above, according to exemplary embodiments of the present disclosure, a method of manufacturing a light source module and a method of manufacturing a lighting device capable of effectively addressing related art problems in manufacturing a chip-on-board type light source module using an LED for flipchip bonding may be provided.

Advantages and effects of the present disclosure are not limited to the foregoing content and may be easily understood from the described specific exemplary embodiments of the present disclosure.

While exemplary embodiments have been shown and described above, it will be apparent to those skilled in the art that modifications and variations could be made without departing from the spirit and scope of the present disclosure as defined by the appended claims.

What is claimed is:

1. A method of manufacturing a light source module, the method comprising:
preparing a board including circuit wirings and a lens having an accommodation groove formed in a bottom surface thereof to be in contact with the board;
attaching a buffer film to a bottom surface of the accommodation groove of the lens;
mounting and arranging a plurality of light emitting devices on one surface of the board such that the plurality of light emitting devices are electrically connected to the circuit wirings;
mounting the lens on the board such that the plurality of light emitting devices are accommodated within the accommodation groove in a state in which the buffer film faces the plurality of light emitting devices; and
attaching the lens to the board through thermo-compression such that the buffer film is tightly attached to upper surfaces of the plurality of light emitting devices and the bottom surface of the accommodation groove.

2. The method of claim 1, wherein the plurality of light emitting devices are arranged in a longitudinal direction of the board, and the accommodation groove extends in the longitudinal direction of the board to integrally cover the plurality of light emitting devices.

3. The method of claim 1, wherein the buffer film extends in the longitudinal direction of the board.

4. The method of claim 1, wherein the attaching of a buffer film comprises attaching an exposed upper surface of the buffer film supported by a support film to the bottom surface of the accommodation groove and subsequently removing the support film.

5. The method of claim 1, wherein, in the mounting of the plurality of light emitting devices, the plurality of light emitting devices each include electrode pads exposed in the same direction, and the plurality of light emitting devices are mounted on and electrically connected to the board by connecting the electrode pads and the circuit wirings through flipchip bonding.

6. The method of claim 1, further comprising forming a resin portion filling a space between the plurality of light emitting devices and the board, before mounting the lens and after mounting the plurality of light emitting devices.

7. The method of claim 6, wherein the resin portion is formed by providing a highly thermally conductive filler and/or a highly light-reflective filler in a resin.

8. The method of claim 1, wherein the lens comprises a flange portion placed on the board so as to be in contact with the board and a lens portion protruded upwardly from the flange portion above the accommodation groove.

9. The method of claim 8, wherein the lens portion extends along the plurality of light emitting devices arranged in the longitudinal direction of the board.

10. The method of claim 8, wherein the lens further includes a fixing pin extending from a bottom surface of the flange portion facing the board, and the board further includes a through hole allowing the fixing pin to be inserted thereinto, and in the mounting of the lens on the board, the fixing pin is inserted into the through hole such that an end portion of the fixing pin is partially protruded through the board from an outer surface of the board.

11. The method of claim 10, wherein, in the attaching of the lens to the board, the lens is fixed to the board through thermo-compression such that the end portion of the fixing pin partially protruded to the outer surface of the board is radially spread on the outer surface of the board.

12. The method of claim 11, wherein the board has a recess formed along the circumference of the through hole in order to accommodate the end portion of the fixing pin radially spread on the outer surface thereof.

13. A method of manufacturing a light source module, the method comprising:
preparing a board on which a plurality of light emitting devices are mounted and arranged in a longitudinal direction on one surface thereof and a lens having an accommodation groove accommodating the plurality of light emitting devices;
attaching a buffer film to a bottom surface of the accommodation groove of the lens;
mounting the lens on the board such that the buffer film faces the plurality of light emitting devices; and
attaching the lens to the board through thermo-compression such that the buffer film is tightly attached to upper surfaces of the plurality of light emitting devices and the bottom surface of the accommodation groove.

14. The method of claim 13, wherein the attaching of a buffer film comprises attaching an exposed upper surface of the buffer film supported by a support film to the bottom surface of the accommodation groove and subsequently removing the support film.

15. The method of claim 13, wherein the buffer film extends in the longitudinal direction of the board, together with the accommodation groove.

16. The method of claim 13, wherein the lens includes a flange portion disposed to be in contact with the board and extending in the longitudinal direction of the board and a lens portion protruded upwardly from the flange portion and extending in the longitudinal direction of the board above the accommodation groove.

17. A method of manufacturing a light source module comprising:
mounting a light emitting device on a board by connecting an electrode pad of the light emitting device to a wiring of the board; and
attaching a buffer film to a bottom surface of an accommodation groove of the lens and mounting the lens on the board such that the buffer film faces an upper surface the light emitting device and is tightly attached to the upper surface of the light emitting device and the bottom surface of the accommodation groove,
wherein a reflective index of the buffer film is greater than that of the light emitting device and smaller than or equal to that of the lens.

18. The method of claim 17, wherein the attaching of the buffer film comprises attaching an exposed upper surface of the buffer film supported by a support film to the bottom surface of the accommodation groove and subsequently removing the support film.

19. The method of claim 17, further comprising:
mounting the light source module in a housing; and
fastening a cover to the housing to cover the light source module.

20. The method of claim 17, further comprising:
mounting the light source module in a housing; and
fastening a heat sink to the housing.
